(19) United States
(12) Patent Application Publication
(10) Pub. No.: US 2026/0081570 A1
(43) Pub. Date: Mar. 19, 2026

(54) CLASS AB AMPLIFIER

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Manabu YAMADA, Ota Tokyo (JP); Shigeyasu Iwata, Hamura Tokyo (JP); Yoshihiro Fukawa, Kawasaki Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/050,192

(22) Filed: Feb. 11, 2025

(30) Foreign Application Priority Data
Sep. 18, 2024 (JP) 2024-160863

(51) Int. Cl. H03F 3/21; H03F 3/45

(52) U.S. Cl. CPC H03F 3/21; H03F 3/45179

(57) ABSTRACT

The class AB amplifier device includes an input chopper switch circuit that performs a chopping operation in synchronization with a first and second chopper clock signal, and outputs first and second modulated signals obtained by modulating the first and second differential input signals to a first and second node; an input amplifier circuit that receives the first and second modulated signals via the first and second nodes, and outputs a differential amplified signal obtained by amplifying the first and second modulated signals; an output chopper switch circuit that receives the differential amplified signal, performs a chopping operation in synchronization with the first and second chopper clock signals, and modulates the differential amplified signal to output a demodulated signal demodulated to the frequency band of the first and second differential input signals; and an output amplifier circuit that outputs a first output signal obtained by amplifying the demodulated signal.

### CROSS-REFERENCE TO RELATED APPLICATIONS

This application is based upon and claims the benefit of priority from the prior Japanese Patent Application No. 2024-160863, filed on Sep. 18, 2024 the entire contents of which are incorporated herein by reference.

### FIELD

This embodiment relates to a class AB amplifier.

### BACKGROUND

For example, in applications that require low noise at low frequencies, it is common to apply a chopper switch to the amplifier.

In such an amplifier device, the effect of the on-resistance of the chopper switch on the circuit characteristics of the amplifier device can sometimes be a problem.

### BRIEF DESCRIPTION OF THE DRAWINGS

FIG. 1 is a diagram showing an example of the configuration of a class AB amplifier device (fully differential class AB amplifier device) according to a first embodiment.

FIG. 2 is a diagram showing an example of the configuration of a feedback circuit included in the class AB amplifier device according to the first embodiment shown in FIG. 1.

FIG. 3 is a diagram showing an example of the configuration of a bias voltage generation circuit applied to the class AB amplifier device according to the first embodiment shown in FIG. 1.

FIG. 4 is a diagram showing an example of the configuration of a class AB amplifier device (single-phase output class AB amplifier device) according to a second embodiment.

### DETAILED DESCRIPTION

An object of one embodiment is to provide a class AB amplifier capable of reducing the effect of the on-resistance of a chopper switch on the circuit characteristics of the class AB amplifier.

A class AB amplifier according to an embodiment comprising:
an input chopper switch circuit that receives first and second differential input signals via first and second input terminals, performs a chopping operation in synchronization with first and second chopper clock signals, and outputs first and second modulated signals obtained by modulating the first and second differential input signals to first and second nodes;
an input amplifier circuit that receives the first and second modulated signals via the first and second nodes, and outputs differentially amplified signals obtained by amplifying the first and second modulated signals;
an output chopper switch circuit that receives the differentially amplified signals, performs a chopping operation in synchronization with the first and second chopper clock signals, and modulates the differentially amplified signals to output demodulated signals demodulated to the frequency bands of the first and second differential input signals; and
an output amplifier circuit that receives the demodulated signals, and outputs a first output signal obtained by amplifying the demodulated signals via a first output terminal.

Below, the class AB amplifier according to the embodiment will be described in detail with reference to the attached drawings. Note that the present invention is not limited to these embodiments.

### First Embodiment

### [Class AB Amplifier]

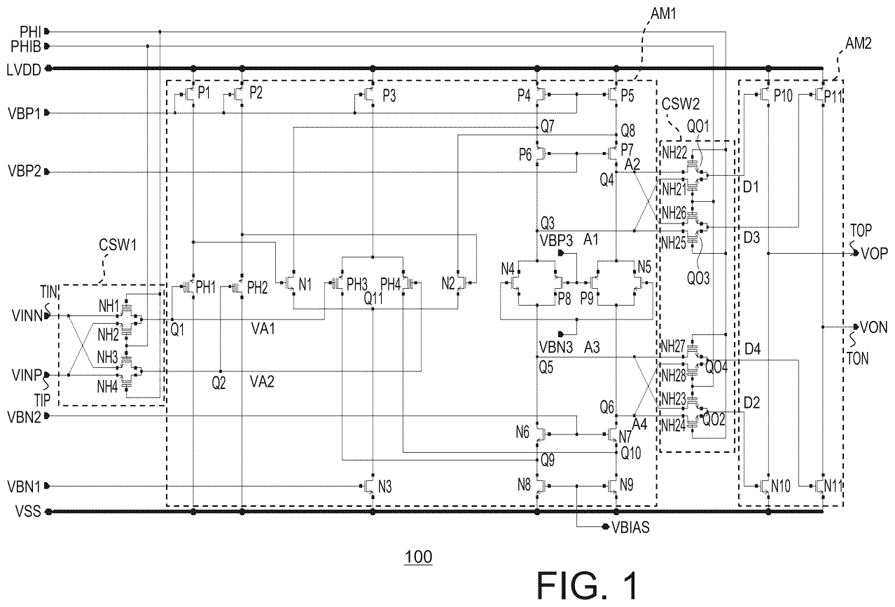

FIG. 1 shows an example of the configuration of a class AB amplifier (fully differential class AB amplifier) according to the first embodiment.

As shown in FIG. 1, the class AB amplifier 100 according to the first embodiment is a fully differential class AB amplifier that receives first and second differential input signals VINN, VINP and outputs first and second output signals VOP, VON that are obtained by amplifying the first and second differential input signals VINN, VINP.

As shown in FIG. 1, the class AB amplifier device 100 includes, for example, an input chopper switch circuit CSW1, an input amplifier circuit AM1, an output chopper switch circuit CSW2, and an output amplifier circuit AM2.

These components of the class AB amplifier 100 are described in detail below.

### [Input Chopper Switch Circuit]

The input chopper switch circuit CSW1 functions as a multiplier that operates in synchronization with the first and second chopper clock signals PHI and PHIB.

Note that the first chopper clock signal PHI and the second chopper clock signal PHIB are complementary clock signals. The high level of the first chopper clock signal PHI and the second chopper clock signal PHIB is a high potential HVDD that is higher than the power supply potential LVDD. The low level of the first chopper clock signal PHI and the second chopper clock signal PHIB is the ground potential VSS.

As shown in FIG. 1, for example, this input chopper switch circuit CSW includes a first input chopper nMOS transistor NH1, a second input chopper nMOS transistor NH2, a third input chopper nMOS transistor NH3, and a fourth input chopper nMOS transistor NH4.

The first input chopper nMOS transistor NH1 has one end (source) connected to the first input terminal TIN and receiving the first differential input signal VINN, the other end (drain) connected to the first node Q1, and a gate receiving the first chopper clock signal PHI.

The second input chopper nMOS transistor NH2 has one end (source) connected to the second input terminal TIP and receiving the second differential input signal VINP, the other end (drain) connected to the first node Q1, and a gate receiving the second chopper clock signal PHIB.

The third input chopper nMOS transistor NH3 has one end (source) connected to the first input terminal TIN and receiving the first differential input signal VINN, the other end (drain) connected to the second node Q2, and a gate receiving the first chopper clock signal PHI.

The fourth input chopper nMOS transistor NH4 has one end (source) connected to the second input terminal TIP and receiving the second differential input signal VIN, the other end (drain) connected to the second node Q2, and a gate receiving the second chopper clock signal PHIB.

The first to fourth input chopper nMOS transistors NH1, NH2, NH3, and NH4 are MOS transistors that can be driven at a high voltage HVDD (e.g., 5 V) higher than the power supply potential LVDD (e.g., 1.5 V).

The input chopper switch circuit CSW1 having such a circuit configuration receives the first and second differential input signals VINN, VINP via the first and second input terminals TIN, TIP, as shown in FIG. 1, and performs chopping operation in synchronization with the first and second chopper clock signals PHI, PHIB, and outputs the first and second modulated signals VA1, VA2, obtained by modulating the first and second differential input signals VINN, VINP (in the odd harmonic band of the chopper clock signals PHI, PHIB), to the first and second nodes Q1, Q2.

It is noted that the circuit configuration of the input chopper switch circuit CSW1 shown in FIG. 1 is just one example, and it may be configured with other circuit configurations that can perform similar functions.

### [Input Amplifier Circuit]

The input amplifier circuit AM1 functions as an amplifier that receives the first and second modulated signals VA1 and VA2 via the first and second nodes Q1 and Q2, and outputs a differential amplified signal obtained by amplifying the first and second modulated signals VA1 and VA2.

As shown in FIG. 1, the input amplifier circuit AM1 includes a first current source pMOS transistor P1, a second current source pMOS transistor P2, a third current source pMOS transistor P3, a fourth current source pMOS transistor P4, a fifth current source pMOS transistor P5, a sixth current source pMOS transistor P6, a seventh current source pMOS transistor P7, an eighth current source pMOS transistor P8, a ninth current source pMOS transistor P9, a first high-voltage drive pMOS transistor PH1, a second high-voltage drive The current source nMOS transistor N1 includes a first control pMOS transistor PH2, a third high-voltage drive pMOS transistor PH3, a fourth high-voltage drive pMOS transistor PH4, a first control nMOS transistor N1, a second control nMOS transistor N2, a third current source nMOS transistor N3, a fourth current source nMOS transistor N4, a fifth current source nMOS transistor N5, a sixth current source nMOS transistor N6, a seventh current source nMOS transistor N7, an eighth current source nMOS transistor N8, and a ninth current source nMOS transistor N9.

The first current source pMOS transistor P1 has one end (source) connected to the power supply potential LVDD, the other end (drain), and a gate to which a first bias voltage VBP1 is applied.

The first high-voltage driving pMOS transistor PH1 has one end (source) connected to the other end (drain) of the first current source pMOS transistor P1, the other end (drain) connected to the ground potential VSS, and a gate connected to the first node Q1 and to which the first modulation signal VA1 is input.

The second current source pMOS transistor P2 has one end (source) connected to the power supply potential LVDD and a gate to which the first bias voltage VBP1 is applied.

The second high-voltage driving pMOS transistor PH2 has one end (source) connected to the other end (drain) of the second current source pMOS transistor P2, the other end (drain) connected to the ground potential VSS, and a gate connected to the second node Q2 and to which the second modulation signal VA2 is input.

The third current source pMOS transistor P3 has one end (source) connected to the power supply potential LVDD, the other end (drain), and a gate to which the first bias voltage VBP1 is applied.

The third high-voltage driving pMOS transistor PH3 has one end (source) connected to the other end (drain) of the third current source pMOS transistor P3, the other end (drain) connected to a ninth node Q9, and a gate connected to the first node Q1 and receiving the first modulation signal VA1.

The fourth high-voltage driving pMOS transistor PH4 has one end (source) connected to the other end (drain) of the third current source pMOS transistor P3, the other end (drain) connected to the tenth node Q10, and a gate connected to the second node Q2 and receiving the second modulation signal VA2.

The first control nMOS transistor N1 has one end (drain) connected to the seventh node Q7, the other end (source) connected to the eleventh node Q11, and a gate at the other end (drain) of the first current source pMOS transistor P1.

The second control nMOS transistor N2 has one end (drain) connected to the eighth node Q8, the other end (source) connected to the eleventh node Q11 (the other end (source) of the first control nMOS transistor N1), and a gate connected to the other end (drain) of the second current source pMOS transistor P2.

The third current source nMOS transistor N3 has one end (drain) connected to the eleventh node Q11 (the other end (source) of the first control nMOS transistor N1), the other end (source) connected to the ground potential VSS, and a gate to which the third bias voltage VBN1 is applied.

Furthermore, the fourth current source pMOS transistor P4 has one end (source) connected to the power supply potential LVDD, the other end (drain) connected to the seventh node Q7, and a gate to which the first bias voltage VBP1 is applied.

The fifth current source pMOS transistor P5 has one end (source) connected to the power supply potential LVDD, the other end (drain) connected to the eighth node Q8, and a gate connected to the gate of the fourth current source pMOS transistor P4 and to which the first bias voltage VBP1 is applied.

The sixth current source pMOS transistor P6 has one end (source) connected to the seventh node Q7 (the other end (drain) of the fourth current source pMOS transistor P4), the other end (drain) connected to the third node Q3, and a gate to which the second bias voltage VBP2 is applied.

The seventh current source pMOS transistor P7 has one end (source) connected to the eighth node Q8 (the other end (drain) of the fifth current source pMOS transistor P5), the other end (drain) connected to the fourth node Q4, and a gate to which the second bias voltage VBP2 is applied.

The eighth current source pMOS transistor P8 has one end (source) connected to the third node Q3 (the other end (drain) of the sixth current source pMOS transistor P6), the other end (drain) connected to the fifth node Q5, and a gate to which a fifth bias voltage VBP3 is applied.

The ninth current source pMOS transistor P9 has one end (source) connected to the fourth node Q4 (the other end (drain) of the seventh current source pMOS transistor P7), the other end (drain) connected to the sixth node Q6, and a gate connected to the gate of the eighth current source pMOS transistor P8 and to which the fifth bias voltage VBP3 is applied.

Furthermore, the fourth current source nMOS transistor N4 has one end (drain) connected to the third node Q3 (the other end (drain) of the sixth current source pMOS transistor P6), the other end (source) connected to the fifth node Q5, and a gate to which a sixth bias voltage VBN3 is applied.

The fifth current source nMOS transistor N5 has one end (source) connected to the fourth node Q4 (the other end (drain) of the seventh current source pMOS transistor P7), the other end (drain) connected to a sixth node Q6, and a gate connected to the gate of the fourth current source nMOS transistor N4 and to which a sixth bias voltage VBN3 is applied.

The sixth current source nMOS transistor N6 has one end (drain) connected to the third node Q3 (the other end (drain) of the sixth current source pMOS transistor P6), the other end (source) connected to the fifth node Q5, and a gate to which the fourth bias voltage VBN2 is applied.

The seventh current source nMOS transistor N7 has one end (drain) connected to the fourth node Q4 (the other end (drain) of the seventh current source pMOS transistor P7), the other end (source) connected to the sixth node Q6, and a gate connected to the gate of the sixth current source nMOS transistor N6 and to which the fourth bias voltage VBN2 is applied.

The eighth current source nMOS transistor N8 has one end (drain) connected to the ninth node Q9 (the other end (source) of the sixth current source nMOS transistor N6), the other end (source) connected to the ground potential VSS, and a gate to which the control bias voltage VBIAS is applied.

The ninth current source nMOS transistor N9 has one end (drain) connected to the tenth node Q10 (the other end (source) of the seventh current source nMOS transistor N7), the other end (source) connected to the ground potential VSS, and a gate connected to the gate of the eighth current source nMOS transistor N8 and to which the control bias voltage VBIAS is applied.

It is noted that the first to fourth bias voltages VBP1, VBP2, VBN1, and VBN2 are set so that the MOS transistors whose gates are connected to them operate in the saturation region.

Furthermore, the fifth bias voltage VBP3 and the sixth bias voltage VBN3 are set so that each MOS transistor to whose gate these bias voltages are applied operates in the saturation region. Furthermore, for example, the fifth bias voltage VBP3 is generated based on the third and fourth bias voltages VBN1, VBN2. Furthermore, the sixth bias voltage VBN3 is generated based on the first and second bias voltages VBP1, VBP2.

Furthermore, the control bias voltage VBIAS is controlled, for example, so that the common voltage between the first output signal VOP and the second output signal VON is maintained at a preset voltage VCM.

In addition, in this input amplifier circuit AM1, the first to fourth high-voltage driven pMOS transistors PH1, PH2, PH3, PH4 are MOS transistors that can be driven at a high voltage HVDD (e.g., 5 V) that is higher than the power supply potential LVDD (e.g., 1.5 V). The other MOS transistors are MOS transistors that can be driven at the power supply potential LVDD.

As already mentioned, the input amplifier circuit AM1 having such a circuit configuration is configured, for example, as shown in FIG. 1, to receive the first and second modulated signals VA1, VA2 via the first and second nodes Q1, Q2, and output differentially amplified signals A1, A2, A3, A4 obtained by amplifying the first and second modulated signals VA1, VA2.

In particular, the input amplifier circuit AM1 outputs, as the differentially amplified signals A1, A2, A3, A4, a first amplified signal A1 and a second amplified signal A2 obtained by differentially amplifying the first and second modulated signals VA1 and VA2, respectively, and a third amplified signal A3 and a fourth amplified signal A4 obtained by differentially amplifying the first and second modulated signals VA1 and VA2, respectively.

It is noted that the circuit configuration of the input amplifier circuit AM1 shown in FIG. 1 is just one example, and the input amplifier circuit AM1 may be configured with another circuit configuration that can perform a similar function.

### [Output Chopper Switch Circuit]

The output chopper switch circuit CSW2 functions as a multiplier that operates in synchronization with the first and second chopper clock signals PHI and PHIB.

This output chopper switch circuit CSW2 includes, for example, first switching MOS transistor circuits NH21, NH22 and second switching MOS transistor circuits NH23, NH24, as shown in FIG. 1.

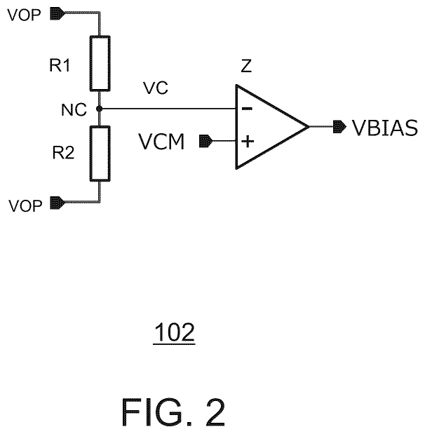

The first switching MOS transistor circuits NH21, NH22 operate in synchronization with the first and second chopper clock signals PHI, PHIB, alternately switching the input first and second amplified signals A1, A2, and outputting the first demodulated signal D1 among the demodulated signals D1, D2, D3, D4. As shown in FIG. 2, the first switching MOS transistor circuits NH21, NH22 are composed of a first output chopper nMOS transistor NH21 and a second output chopper nMOS transistor NH22.

The second switching MOS transistor circuits NH23, NH24 operate in synchronization with the first and second chopper clock signals PHI, PHIB, alternately switching the input third and fourth amplified signals A3, A4, and outputting them as the second demodulated signal D2 among the demodulated signals D1, D2, D3, D4. As shown in FIG. 2, the second switching MOS transistor circuits NH23, NH24 are composed of a third output chopper nMOS transistor NH23 and a fourth output chopper nMOS transistor NH24.

It is noted that the first demodulated signal D1 and the second demodulated signal D2 are in-phase signals whose voltages change in the same direction.

Furthermore, the output chopper switch circuit CSW2 includes, for example, a third switching MOS transistor circuit NH25, NH26 and a fourth switching MOS transistor circuit NH27, NH28, as shown in FIG. 1.

The third switching MOS transistor circuits NH25, NH26 operate in synchronization with the first and second chopper clock signals PHI, PHIB, alternately switching the input first and second amplified signals A, A2, and outputting the third demodulated signal D3 among the demodulated signals D1, D2, D3, D4. The third switching MOS transistor circuits NH25, NH26 are composed of a fifth output chopper nMOS transistor NH25 and a sixth output chopper nMOS transistor NH26, as shown in FIG. 2.

Furthermore, the fourth switching MOS transistor circuits NH27, NH28 operate in synchronization with the first and second chopper clock signals PHI, PHIB, alternately switching between the input third and fourth amplified signals A3, A4, and outputting the fourth demodulated signal D4 among the demodulated signals D1, D2, D3, and D4.

It is noted that the first demodulated signal D1 and the third demodulated signal D3 are mutually complementary differential signals. The second demodulated signal D2 and the fourth demodulated signal D4 are mutually complementary differential signals. The third demodulated signal D3 and the fourth demodulated signal D4 are in-phase signals whose voltages change in the same direction.

More specifically, the output chopper switch circuit CSW2 comprises, for example, as shown in FIG. 1, a first output chopper nMOS transistor NH21, a second output chopper nMOS transistor NH22, a third output chopper nMOS transistor NH23, a fourth output chopper nMOS transistor NH24, a fifth output chopper nMOS transistor NH25, a sixth output chopper nMOS transistor NH26, a seventh output chopper nMOS transistor NH27, and an eighth output chopper nMOS transistor NH28.

The first output chopper nMOS transistor NH21 has one end (drain) connected to the third node Q3 and inputting the first amplified signal A1 obtained by amplifying the first modulation signal VA1, the other end (source) connected to the first demodulation node QO1, and a gate to which the second chopper clock signal PHIB is input.

The second output chopper nMOS transistor NH22 has one end (drain) connected to the fourth node Q4 and inputting the second amplified signal A2 obtained by amplifying the second modulation signal VA2, the other end (source) connected to the first demodulation node QO1, and a gate to which the first chopper clock signal PHI is input.

The third output chopper nMOS transistor NH23 has one end (drain) connected to the fifth node Q5 and inputting the third amplified signal A3 obtained by amplifying the first modulation signal VA1, the other end (source) connected to the second demodulation node QO2, and a gate to which the second chopper clock signal PHIB is input.

The fourth output chopper nMOS transistor NH24 has one end (drain) connected to the sixth node Q6 and inputting the fourth amplified signal A4 obtained by amplifying the second modulation signal VA2, the other end (source) connected to the second demodulation node QO2, and a gate to which the first chopper clock signal PHI is input.

Furthermore, the fifth output chopper nMOS transistor NH25 has one end (drain) connected to the third node Q3 and to which the first amplified signal AP1 is input, the other end (source) connected to the third demodulation node QO3, and a gate to which the first chopper clock signal PHI is input.

The sixth output chopper nMOS transistor NH26 has one end (drain) connected to the fourth node Q4 and to which the second amplified signal AP2 is input, the other end (source) connected to the third demodulation node QO3, and a gate to which the second chopper clock signal PHIB is input.

The seventh output chopper nMOS transistor NH27 has one end (drain) connected to the fifth node Q5 and to which the third amplified signal A3 is input, the other end (source) connected to the fourth demodulation node QO4, and a gate to which the first chopper clock signal PHI is input.

The eighth output chopper nMOS transistor NH28 has one end (drain) connected to the sixth node Q6 and to which the fourth amplified signal A4 is input, the other end (source) connected to the fourth demodulation node QO4, and a gate to which the second chopper clock signal PHIB is input.

The output chopper switch circuit CSW2 having such circuit protection receives the differential amplified signals A1, A2, A3, A4 as input, and performs chopping operation in synchronization with the chopper clock signals PHI, PHIB to modulate the differential amplified signals A1, A2, A3, A4, thereby outputting demodulated signals D1, D2, D3, D4 demodulated to the frequency bands of the first and second differential input signals VINN, VINP.

It is noted that the circuit configuration of the output chopper switch circuit CSW2 shown in FIG. 1 is just one example, and it may be configured with other circuit configurations that can perform similar functions.

### [Output Amplifier Circuit]

The output amplifier circuit AM2 functions as an amplifier that amplifies the demodulated signal and outputs an output signal.

As shown in FIG. 1, for example, the output amplifier circuit AM2 receives demodulated signals D1, D2, D3, and D4 as input, and outputs first and second output signals VOP and VON, which are output signals obtained by amplifying the demodulated signals D1, D2, D3, and D4, via output terminals TOP and TON.

As shown in FIG. 1, the output amplifier circuit AM2 includes, for example, a first output amplifier pMOS transistor P10, a first output amplifier nMOS transistor N10, a second output amplifier MOS transistor P11, and a second output amplifier nMOS transistor N11.

The first output amplification pMOS transistor P10 has one end (source) connected to the power supply potential LVDD, the other end (drain) connected to the first output terminal TOP, and a gate connected to the first demodulation node QO1 and receiving the first demodulation signal D1.

The first output amplification nMOS transistor N10 has one end (source) connected to the ground potential VSS, the other end (drain) connected to the first output terminal TOP, and a gate connected to the second demodulation node QO2 and receiving the second demodulation signal D2.

The second output amplification pMOS transistor P11 has one end (source) connected to the power supply potential LVDD, the other end (drain) connected to the second output terminal TON, and a gate to which the third demodulated signal D3 is input.

The second output amplification nMOS transistor N11 has one end (source) connected to the ground potential VSS, the other end (drain) connected to the second output terminal TON, and a gate to which the fourth demodulated signal D4 is input.

The output amplifier circuit AM2 having such a circuit configuration outputs a first output signal VOP obtained by amplifying the first and second demodulation signals D1, D2 via the first output terminal TOP, and outputs a second output signal VON obtained by amplifying the third and fourth demodulation signals D3, D4 via the second output terminal TON. The first output signal VOP and the second output signal VON are complementary differential signals.

### [Feedback Circuit]

Here, FIG. 2 is a diagram showing an example of the configuration of a feedback circuit applied to the class AB amplifier device according to the first embodiment shown in FIG. 1.

The class AB amplifier device 100 according to the first embodiment may further include a feedback circuit 102 shown in FIG. 2, if necessary.

This feedback circuit 102 controls the gain of the input amplifier circuit AM1 so that the common voltage VC of the first output signal VOP and the second output signal VON output by the output amplifier circuit AM2 is maintained at (approaching) a preset voltage VCM.

This feedback circuit 102 has, for example, a first resistor R1, a second resistor R2, and an error amplifier Z, as shown in FIG. 2.

The first resistor R1 has one end to which the first output signal VOP is applied and the other end connected to a common node NC from which a common voltage VC is output.

The second resistor R2 has one end to which the second output signal VON is applied and the other end connected to a common node NC from which a common voltage VC is output.

A common voltage VC is input to the inverting input terminal of the error amplifier Z, a set voltage VCM is input to the non-inverting input terminal, and a control bias voltage VBIAS corresponding to the difference between the common voltage VC and the set voltage VCM is output.

That is, the feedback circuit 102 controls the control bias voltage VBIAS applied to the gates of the eighth and ninth current source nMOS transistors N8 and N9 so that the common voltage VC of the first output signal VOP and the second output signal VON is maintained at a preset voltage VCM.

This controls the current flowing through the eighth and ninth current source nMOS transistors N8, N9, thereby controlling the voltage of the differential amplification signals A1 to A4. This controls the voltage of the first to fourth modulation signals D1 to D4, causing the first and second output amplification pMOS transistors P10, P11 and the first and second output amplification nMOS transistors N10, N11 to operate so that the common voltage VC of the first output signal VOP and the second output signal VON is maintained at the preset set voltage VCM.

That is, the gain of the input amplifier circuit AM1 is controlled so that the common voltage VC of the first output signal VOP and the second output signal VON is maintained at a preset set voltage VCM.

It is noted that the circuit configuration of the feedback circuit 102 shown in FIG. 2 is just an example, and the circuit may be configured with other circuit configurations that can perform similar functions.

### [Bias Voltage Generating Circuit]

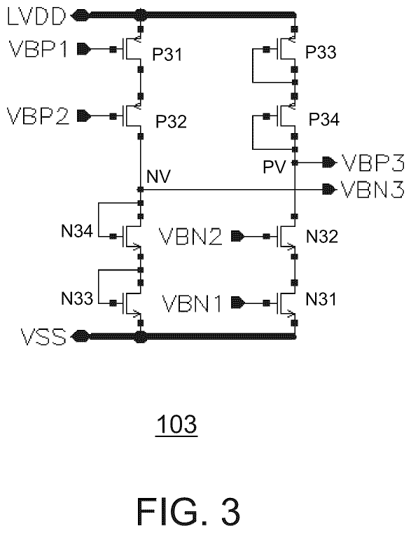

Here, FIG. 3 is a diagram showing an example of the configuration of a bias voltage generating circuit applied to the class AB amplifier according to the first embodiment shown in FIG. 1.

The class AB amplifier 100 according to the first embodiment may further include a bias voltage generating circuit 103 as shown in FIG. 3, if necessary.

This bias voltage generation circuit 103 generates a fifth bias voltage VBP3 based on the third and fourth bias voltages VBN1, VBN2, and also generates a sixth bias voltage VBN3 based on the first and second bias voltages VBP1, VBP2.

As shown in FIG. 3, for example, the bias voltage generation circuit 103 includes a first bias pMOS transistor P31, a second bias pMOS transistor P32, a third bias pMOS transistor P33, a fourth bias pMOS transistor P34, a first bias nMOS transistor N31, a second bias nMOS transistor N32, a third bias nMOS transistor N33, and a fourth bias nMOS transistor N34.

The first bias pMOS transistor P31 has one end (source) connected to the power supply potential LVDD, the other end (drain), and a gate to which the first bias voltage VBP1 is applied.

The second bias pMOS transistor P32 has one end (source) connected to the other end (drain) of the first bias pMOS transistor P31, the other end (drain) connected to a second bias voltage node NV from which the sixth bias voltage VBN3 is output, and a gate to which the second bias voltage VBP2 is applied.

The third bias pMOS transistor P33 has one end (source) connected to the power supply potential LVDD, the other end (drain), and a gate, and is diode-connected.

The fourth bias pMOS transistor P34 has one end (source) connected to the other end (drain) of the third bias pMOS transistor P33, the other end (drain) connected to the first bias voltage node PV, and a gate, and is diode-connected.

Furthermore, the first bias nMOS transistor N31 has one end (source) connected to the ground potential VSS, the other end (drain), and a gate to which the third bias voltage VBN1 is applied.

The second bias nMOS transistor N32 has one end (source) connected to the other end (drain) of the first bias nMOS transistor N31, the other end (drain) connected to the first bias voltage node PV from which the fifth bias voltage VBP3 is output, and a gate to which the fourth bias voltage VBN2 is applied.

The third bias nMOS transistor N33 has one end (source) connected to the ground potential VSS, the other end (drain), and a gate, and is diode-connected.

The fourth bias nMOS transistor N34 has one end (source) connected to the other end (drain) of the third bias nMOS transistor N33, the other end (drain) connected to the second bias voltage node NV, and a gate, and is diode-connected.

As described above, the bias voltage generating circuit 103 having such a circuit configuration generates a fifth bias voltage VBP3 based on the third and fourth bias voltages VBN1, VBN2, and generates a sixth bias voltage VBN3 based on the first and second bias voltages VBP1, VBP2.

It is noted that that the circuit configuration of the bias voltage generation circuit 103 shown in FIG. 3 is just an example, and it may be configured with other circuit configurations that can perform similar functions.

### [Operation of the Class AB Amplifier 100]

Next, an example of the operation of the class AB amplifier 100 having the above configuration will be described.

Here, as already described, the input chopper switch circuit CSW1 of the class AB amplifier 100 receives the first and second differential input signals VINN, VINP via the first and second input terminals TIN, TIP, as shown in FIG. 1, for example, and performs chopping operation in synchronization with the first and second chopper clock signals PHI, PHIB to output the first and second modulated signals VAN, VAP obtained by modulating the first and second differential input signals VINN, VINP (in the odd-order harmonic band of the chopper clock signals PHI, PHIB) to the first and second nodes Q1, Q2.

Then, the input amplifier circuit AM1 outputs a first amplified signal A1 and a second amplified signal A2 obtained by differentially amplifying the first and second modulated signals VA1 and VA2, respectively, and a third amplified signal A3 and a fourth amplified signal A4 obtained by differentially amplifying the first and second modulated signals VA1 and VA2, respectively.

The output chopper switch circuit CSW2 receives the differential amplified signals A1, A2, A3, and A4, and performs chopping operation in synchronization with the chopper clock signals PHI and PHIB to modulate the differential amplified signals A1, A2, A3, and A4, thereby outputting demodulated signals D1, D2, D3, and D4 demodulated to the frequency bands of the first and second differential input signals VINN and VINP.

The output amplifier circuit AM2 outputs a first output signal VOP obtained by amplifying the first and second demodulation signals D1, D2 via the first output terminal TOP, and outputs a second output signal VON obtained by amplifying the third and fourth demodulation signals D3, D4 via the second output terminal TON.

Here, as already described, the output chopper switch circuit CSW2 of the class AB amplifier device 100 according to the first embodiment includes first to fourth switching MOS transistor circuits (first to eighth output choppers NH21 to NH28) for outputting voltage signals (differential modulation signals D1 to D4) to the gates of the MOS transistors constituting the output amplifier circuit AM2.

These first to fourth switching MOS transistor circuits (first to eighth output choppers NH21 to NH28) have a circuit configuration in which no steady-state current flows, so that the effect on the circuit characteristics of fluctuations in on-resistance due to fluctuations in the gate-source voltage of the MOS transistors can be reduced.

In other words, according to the class AB amplifier device 100 of the first embodiment, it is possible to reduce the effect of the on-resistance of the chopper switch on the circuit characteristics.

### Second Embodiment

Here, in the first embodiment described above, a fully differential class AB amplifier device, which is an example of the configuration of a class AB amplifier device, was described. However, the configuration of this class AB amplifier device is not limited to this. Therefore, in this second embodiment, an example of a single-phase output class AB amplifier device with the configuration of a class AB amplifier device will be described.

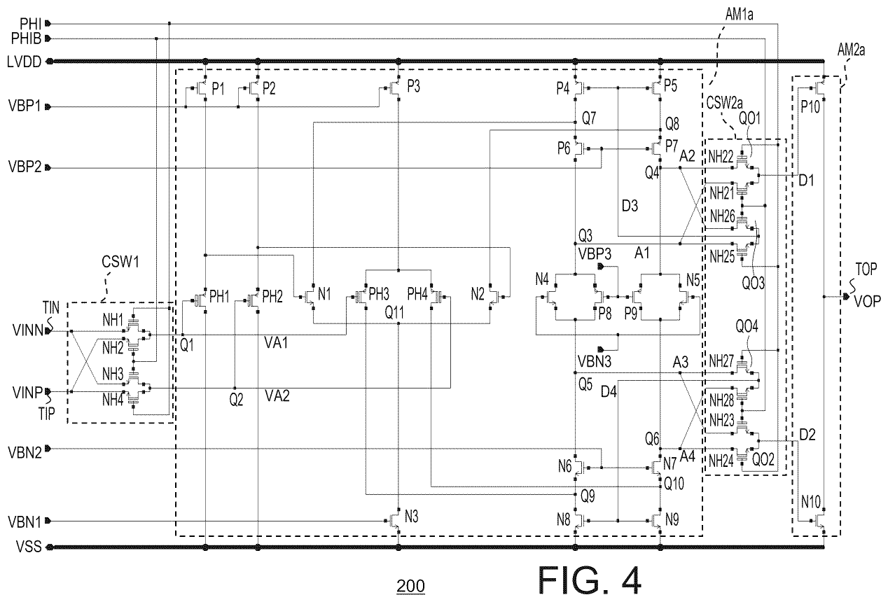

FIG. 4 is a diagram showing an example of the configuration of a class AB amplifier (single-phase output class AB amplifier) according to the second embodiment. In the following description of the class AB amplifier according to the second embodiment, the description of the components having the same reference numerals as those in the first embodiment will be omitted.

As shown in FIG. 4, the class AB amplifier 200 of the second embodiment is a single-phase output class AB amplifier that receives first and second differential input signals VINN, VINP and outputs a first output signal VOP that is an amplified version of the first and second differential input signals VINN, VINP.

The class AB amplifier 200 according to the second embodiment includes, for example, an input chopper switch circuit CSW1, an input amplifier circuit AM1a, an output chopper switch circuit CSW2a, and an output amplifier circuit AM2a, as shown in FIG. 4.

Here, the output amplifier circuit AM2a of the class AB amplifier device 200 has a single-phase output, and therefore, compared to the output amplifier circuit AM2 of the first embodiment, the second output amplifier MOS transistor P11 and the second output amplifier nMOS transistor N11 are omitted.

Meanwhile, the third demodulation node QO3 of the output chopper switch circuit CSW2a of the class AB amplifier 200 is connected to the gates of the fourth and fifth current source pMOS transistors P4 and P5, and the voltage of this third demodulation node QO3 is applied to the gates of the fourth and fifth current source pMOS transistors P4 and P5 in place of the first bias voltage VBP1.

Furthermore, the fourth demodulation node QO4 of the output chopper switch circuit CSW2a of the class AB amplifier 200 is connected to the gates of the eighth and ninth current source nMOS transistors N8 and N9, and the voltage of this fourth demodulation node QO4 is applied to the gates of the eighth and ninth current source nMOS transistors N8 and N9 in place of the control bias voltage VBIAS.

This makes it possible to omit the feedback circuit 102 used in the class AB amplifier device 100 of the first embodiment.

Note that, similarly to the class AB amplifier 100 according to the first embodiment, the class AB amplifier 200 may be provided with a bias voltage generation circuit by applying the bias voltage generation circuit shown in FIG. 3 described above.

The rest of the configuration and operation of the class AB amplifier 200 of the second embodiment are similar to the configuration and operation of the class AB amplifier 100 of the first embodiment.

Here, as already described, the output chopper switch circuit CSW2a of the class AB amplifier 200 according to the second embodiment includes first and second switching MOS transistor circuits (first to fourth output choppers NH21 to NH24) for outputting voltage signals (differential modulation signals D1 to D2) to the gates of the MOS transistors constituting the output amplifier circuit AM2a.

These first to fourth switching MOS transistor circuits (first to eighth output choppers NH21 to NH28) have a circuit configuration in which no steady-state current flows, so that the effect on the circuit characteristics of fluctuations in on-resistance due to fluctuations in the gate-source voltage of the MOS transistors can be reduced.

In other words, according to the class AB amplifier device of the second embodiment, it is possible to reduce the effect of the on-resistance of the chopper switch on the circuit characteristics.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A class AB amplifier comprising:
an input chopper switch circuit that receives first and second differential input signals via first and second input terminals, performs a chopping operation in synchronization with first and second chopper clock signals, and outputs first and second modulated signals obtained by modulating the first and second differential input signals to first and second nodes;
an input amplifier circuit that receives the first and second modulated signals via the first and second nodes, and outputs differentially amplified signals obtained by amplifying the first and second modulated signals;
an output chopper switch circuit that receives the differentially amplified signals, performs a chopping operation in synchronization with the first and second chopper clock signals, and modulates the differentially amplified signals to output demodulated signals demodulated to the frequency bands of the first and second differential input signals; and
an output amplifier circuit that receives the demodulated signals, and outputs a first output signal obtained by amplifying the demodulated signals via a first output terminal.

2. The class AB amplifier according to claim 1,
wherein the input amplifier circuit outputs, as the differentially amplified signal, a first amplified signal and a second amplified signal obtained by differentially amplifying the first and second modulated signals, respectively, and a third amplified signal and a fourth amplified signal obtained by differentially amplifying the first and second modulated signals, respectively, and
wherein the output chopper switch circuit includes:
a first switching MOS transistor circuit that operates in synchronization with the first and second chopper clock signals, alternately switches between the input first and second amplified signals, and outputs the first demodulated signal among the demodulated signals; and
a second switching MOS transistor circuit that operates in synchronization with the first and second chopper clock signals, alternately switches between the input third and fourth amplified signals, and outputs the second demodulated signal among the demodulated signals.

3. The class AB amplifier device according to claim 2,
wherein the output amplifier circuit comprises:
a first output amplifier pMOS transistor having one end connected to a power supply potential, the other end connected to the first output terminal, and a gate to which the first demodulated signal is input; and
a first output amplifier nMOS transistor having one end connected to a ground potential, the other end connected to the first output terminal, and a gate to which the second demodulated signal is input.

4. The class AB amplifier device according to claim 3, wherein the class AB amplifier device outputs a first output signal obtained by amplifying the first and second demodulated signals via the first output terminal.

5. The class AB amplifier device according to claim 3,
wherein the output chopper switch circuit comprises:
a third switching MOS transistor circuit that operates in synchronization with the first and second chopper clock signals, alternately switches between the input first and second amplified signals, and outputs the third demodulated signal among the demodulated signals; and
a fourth switching MOS transistor circuit that operates in synchronization with the first and second chopper clock signals, alternately switches between the input third and fourth amplified signals, and outputs the fourth demodulated signal among the demodulated signals.

6. The class AB amplifier device according to claim 4,
wherein the output chopper switch circuit comprises:
a third switching MOS transistor circuit that operates in synchronization with the first and second chopper clock signals, alternately switches between the input first and second amplified signals, and outputs the third demodulated signal among the demodulated signals; and
a fourth switching MOS transistor circuit that operates in synchronization with the first and second chopper clock signals, alternately switches between the input third and fourth amplified signals, and outputs the fourth demodulated signal among the demodulated signals.

7. The class AB amplifier device according to claim 5,
wherein the output amplifier circuit comprises:
a second output amplifier pMOS transistor having one end connected to the power supply potential, the other end connected to the second output terminal, and a gate to which the third demodulated signal is input; and
a second output amplifier nMOS transistor having one end connected to the ground potential, the other end connected to the second output terminal, and a gate to which the fourth demodulated signal is input.

8. The class AB amplifier device according to claim 7, wherein the class AB amplifier device outputs a second output signal obtained by amplifying the third and fourth demodulated signals via the second output terminal.

9. The class AB amplifier device according to claim 6,
wherein the output amplifier circuit comprises:
a second output amplifier pMOS transistor having one end connected to the power supply potential, the other end connected to the second output terminal, and a gate to which the third demodulated signal is input; and
a second output amplifier nMOS transistor having one end connected to the ground potential, the other end connected to the second output terminal, and a gate to which the fourth demodulated signal is input.

10. The class AB amplifier device according to claim 9, wherein the class AB amplifier device outputs a second output signal obtained by amplifying the third and fourth demodulated signals via the second output terminal.
